(19) United States
(12) Patent Application Publication
(10) Pub. No.: US 2011/0198507 A1
(43) Pub. Date: Aug. 18, 2011

(54) RADIATION IMAGING APPARATUS, RADIATION GENERATING APPARATUS, RADIATION IMAGING SYSTEM, AND PROCESSING METHOD

(75) Inventor: Tsuyoshi Takegami, Machida-shi (JP)

(73) Assignee: CANON KABUSHIKI KAISHA, Tokyo (JP)

(21) Appl. No.: 13/019,376

(22) Filed: Feb. 2, 2011

(30) Foreign Application Priority Data
Feb. 17, 2010 (JP) 2010-032903
Nov. 26, 2010 (JP) 2010-264295

(51) Int. Cl. H01L 27/146

(52) U.S. Cl. 250/370.08

(57) ABSTRACT

A radiation imaging apparatus comprises: a radiation imaging unit configured to capture an image based on radiation irradiated by a radiation generator; a light receiving unit configured to receive light irradiated on an irradiated region of the radiation generator; and a control unit configured to communicate with a control apparatus of the radiation generator in accordance with reception of light by the light receiving unit.

### BACKGROUND OF THE INVENTION

1. Field of the Invention

The present invention relates to radiation imaging.

2. Description of the Related Art

Recently, a radiation imaging apparatus has been commercialized, which directly digitizes radiographic images by using a radiation sensor having a phosphor in tight contact with solid-state imaging devices for a large screen, that is, a so-called flat panel detector (FPD). An apparatus using such a scheme has been widely used in place of a conventional analog imaging apparatus.

FIG. 11 shows a conventional radiation imaging apparatus. This radiation imaging apparatus includes a radiation generator 91, a control unit 92, two radiation sensors 93, that is, 93a and 93b, and a switch 94. That is, the radiation imaging apparatus shown in FIG. 11 includes the two radiation sensors 93a and 93b for the single radiation generator 91.

The radiation imaging apparatus shown in FIG. 11 is provided with a switch 94, which is switched to select one of the radiation sensors 93a and 93b. The apparatus performs imaging by using the radiation generator 91 and the selected one of the radiation sensors 93a and 93b. That is, when the plurality of radiation sensors 93a and 93b are provided for one radiation generator 91, the operator needs to manually select one of the radiation sensors 93a and 93b.

According to the technique disclosed in Japanese Patent Laid-Open No. 2000-308630, the selected radiation sensor 93b is set in the ready state to allow quick imaging. On the other hand, the radiation sensor 93a that is not selected and hence is not used is set in the sleep state to save power. This suppresses an increase in temperature and also suppresses an increase in dark current.

A radiology technician or the like checks one of the radiation sensors 93a and 93b to be used at the time of radiation imaging. This makes it necessary to use one of the radiation sensors 93a and 93b. Therefore, the operator needs to manually perform such selecting operation.

Referring to the switch 94 in FIG. 11, the radiation generator 91 is connected to the radiation sensor 93b. That is, the selected sensor is the radiation sensor 93b that is not placed on the optical path of radiation. The radiation sensor 93a placed on the optical path of radiation is not connected to the radiation generator 91.

### SUMMARY OF THE INVENTION

The present invention provides a technique that can easily perform radiation imaging even if a plurality of radiation imaging apparatuses are provided.

According to the first aspect of the present invention, there is provided a radiation imaging apparatus comprising: a radiation imaging unit configured to capture an image based on radiation irradiated by a radiation generator; a light receiving unit configured to receive light irradiated on an irradiated region of the radiation generator; and a control unit configured to communicate with a control apparatus of the radiation generator in accordance with reception of light by the light receiving unit.

According to the second aspect of the present invention, there is provided a processing method for a radiation imaging apparatus, comprising: capturing an image based on radiation irradiated by a radiation generator; receiving light irradiated on an irradiated region of the radiation generator; and communicating with a control apparatus of the radiation generator in accordance with reception of light.

According to the third aspect of the present invention, there is provided a radiation generating apparatus comprising: a radiation generating unit configured to emit radiation via a collimator; a light source configured to emit visible light via the collimator; and a modulation unit configured to apply a predetermined modulation to light emitted by the light source.

According to the fourth aspect of the present invention, there is provided a radiation imaging system comprising a radiation generating apparatus and a radiation imaging apparatus, the radiation generating apparatus comprising a radiation generating unit configured to irradiate radiation via a collimator, and an illumination unit configured to irradiate light on an irradiated region of the radiation generating unit, and the radiation imaging apparatus comprising a radiation imaging unit configured to capture an image based on radiation irradiated by the radiation generating unit; a light receiving unit configured to receive light irradiated on an irradiated region of the radiation generating unit; and a control unit configured to communicate with a control apparatus of the radiation generating unit in accordance with reception of light by the light receiving unit.

Further features of the present invention will be apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention, and together with the description, serve to explain the principles of the invention.

FIG. 1 is a view showing an example of the arrangement of a radiation imaging system 70 according to an embodiment of the present invention;

FIGS. 2A to 2D are views each showing an example of the arrangement relationship between a radiation imaging apparatus 30 and a collimator light receiving unit 31;

FIGS. 3A and 3B are views each showing an example of the arrangement relationship between the radiation imaging apparatus 30 and the collimator light receiving unit 31;

FIG. 4 is a flowchart showing an example of the operation of the radiation imaging system 70 shown in FIG. 1;

FIG. 5 is a view showing an example of the arrangement of a radiation imaging system 70 according to the second embodiment;

FIG. 6 is a view showing an example of the arrangement of a radiation imaging system 70 according to the third embodiment;

FIG. 7 is a flowchart showing an example of the operation of the radiation imaging system 70 according to the third embodiment;

FIG. 8 is a view showing an example of the arrangement of a radiation imaging system 70 according to the fourth embodiment;

FIG. 9 is a flowchart showing an example of the operation of the radiation imaging system 70 according to the fourth embodiment;

FIG. 10 is a view showing an example of the arrangement of a digital radiation imaging system according to the fifth embodiment; and

FIG. 11 is a block diagram showing an example of the prior art.

### DESCRIPTION OF THE EMBODIMENTS

An exemplary embodiment(s) of the present invention will now be described in detail with reference to the drawings. It should be noted that the relative arrangement of the components, the numerical expressions and numerical values set forth in these embodiments do not limit the scope of the present invention unless it is specifically stated otherwise.

Note that each embodiment to be described below will exemplify a case in which radiation is used. Radiation includes α-rays, β-rays, and neutron rays, which are particles smaller than atoms, and also includes gamma rays and X-rays. General, simple imaging uses X-rays. Assume therefore that radiation imaging in the following embodiments includes an imaging apparatus using only X-rays.

### First Embodiment

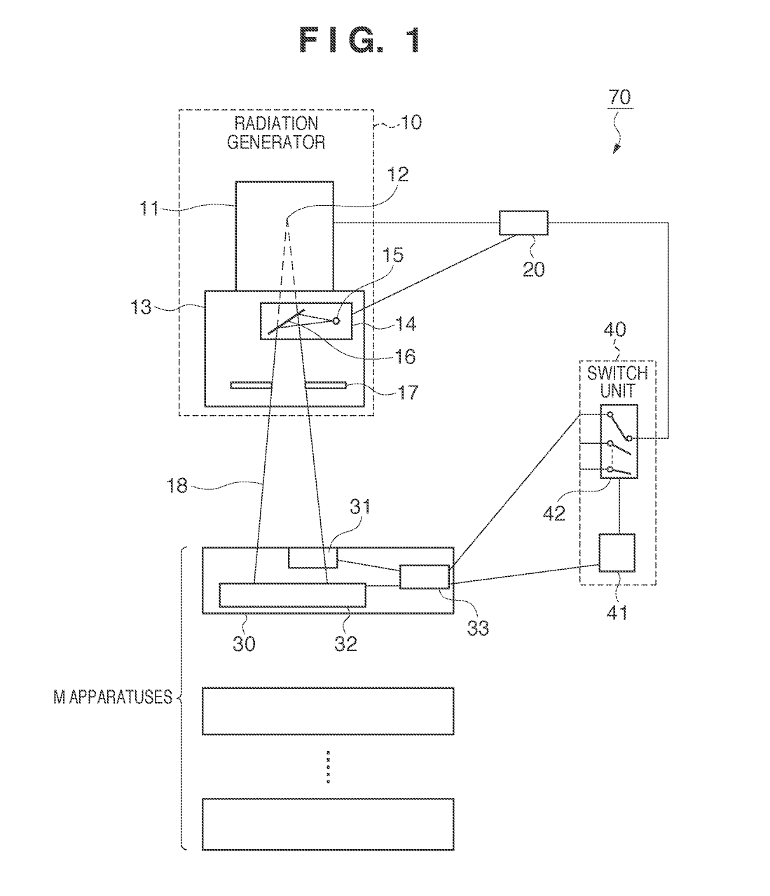

FIG. 1 is a view showing an example of the arrangement of a radiation imaging system according to an embodiment of the present invention. The following is an example in which a plurality of radiation imaging apparatuses 30 can be used for one radiation generator 10.

A radiation imaging system 70 includes the radiation generator 10, a plurality of (M) radiation imaging apparatuses 30, and a switch unit 40. That is, the plurality of radiation imaging apparatuses 30 are provided for the single radiation generator 10. The radiation generator 10 does not correspond one-to-one with the radiation imaging apparatuses 30.

The radiation generator 10 will be described first. The radiation generator 10 irradiates an object (that is, a patient) with radiation. The radiation generator 10 emits radiation via, for example, a collimator. The radiation generator 10 includes a radiation tube 11 and a collimator unit 13.

The radiation tube 11 has a function of irradiating radiation. The radiation tube 11 irradiates radiation from a radiation focus 12 after the irradiation of collimator light (to be described later). Note that the radiation tube 11 irradiates radiation based on a control signal from a radiation control unit 20.

The collimator unit 13 includes a collimator light irradiation unit 14, a reflecting mirror 16, and a blade 17, and has a function of collimating radiation (a function of indicating a radiation irradiation area) and the like.

The reflecting mirror 16 functions as a half mirror, and reflects only visible light while transmitting radiation. The reflecting mirror 16 is implemented by an aluminum plate having a sectional width of several mm. The blade 17 functions as a light-shielding plate, and adjusts the irradiated region of radiation.

The collimator light irradiation unit 14 functions as an illumination unit, and emits visible light (collimator light) coinciding (or almost coinciding) with a radiation path 18 before the irradiation of radiation. This operation is performed to present the operator the radiation path 18 before the irradiation of radiation. This allows the operator to grasp the collimation of radiation. Note that it is necessary to make the radiation path and collimator light path coincide (or almost coincide) with each other in advance, and hence the positional relationship between a light source 15 for collimator light and the reflecting mirror 16 is adjusted in advance.

Each radiation imaging apparatus 30 will be described next. The radiation imaging apparatus 30 accumulates charge based on radiation transmitted through an object. This allows to detect (acquire) a radiographic image of the object. The radiation imaging apparatus 30 has a function of capturing a radiographic image (a radiation detection function), a function of removing accumulated charge (a reset function), a function of receiving collimator light, a function of controlling the switch unit 40 (a switch unit control function), and a function of communicating with the radiation control unit 20.

The radiation imaging apparatus 30 includes a radiation sensor 32, a sensor control unit 33, and a collimator light receiving unit 31. The radiation sensor 32 receives radiation irradiated from the radiation tube 11. The collimator light receiving unit 31 receives collimator light irradiated from the collimator light irradiation unit 14. The collimator light receiving unit 31 is implemented by, for example, a photodiode.

The sensor control unit 33 comprehensively controls the operation of the radiation imaging apparatus 30. Upon receiving collimator light via the collimator light receiving unit 31, the sensor control unit 33 determines that the radiation imaging apparatus 30 is placed in an imaging enable area. In this case, the sensor control unit 33 controls the switch unit 40 to establish a communication path which connects the radiation imaging apparatus 30 to the radiation control unit 20. The sensor control unit 33 receives a reset instruction from the radiation control unit 20 via the communication path and causes the radiation sensor 32 to execute reset operation based on the instruction. That is, in this embodiment, the sensor control unit 33 determines, based on the detection of the reception of collimator light irradiated from the radiation generator 10 (collimator light irradiation unit 14), the radiation imaging apparatus 30 (radiation sensor 32) to execute reset operation. This sensor then executes reset operation.

The radiation control unit 20 will be described next. The radiation control unit 20 has a function of controlling the irradiation of radiation and collimator light (an irradiation control function) and a function of controlling communication with the radiation imaging apparatus 30 (sensor control unit 33).

The radiation control unit 20 determines the possibility of the irradiation of radiation as well as the irradiation of radiation and an irradiation pulse width. When determining the possibility of the irradiation of radiation, the radiation control unit 20 determines first whether it can perform bidirectional (synchronous) communication with the sensor control unit 33. If the determination result indicates that the communication can be performed, the radiation control unit 20 determines whether the radiation imaging apparatus 30 (radiation sensor 32) used for imaging has completed the reset operation. If the reset operation is complete, the radiation control unit 20 outputs an instruction signal to the radiation generator 10 to irradiate radiation.

As another embodiment, the radiation imaging apparatus 30 outputs an irradiation enable signal to the radiation control unit 20 based on the detection of the reception of collimator light. Upon receiving the irradiation enable signal, the radiation control unit 20 issues an instruction to the radiation generator 10. In this case, the switch unit 40 is omitted, and the plurality of radiation imaging apparatuses 30 are connected to the radiation control unit 20. According to this arrangement, since the radiation imaging apparatus 30 outputs an irradiation enable signal, the radiation imaging apparatus 30, which has output the enable signal, receives radiation from the radiation generator 10. This makes it unnecessary to manually select one of the M radiation imaging apparatuses 30 which is to be used for imaging. This greatly reduces the possibility that the radiation imaging apparatus 30 unsuitable for use will be used.

The radiation control unit 20 controls the irradiation intensity and timing of collimator light. Collimator light is a signal having a constant (or almost constant) light intensity. This light intensity is set to be higher than that of environmental light in the installation place. As described above, collimator light becomes a trigger for the reset operation of the radiation imaging apparatus 30 (radiation sensor 32). In addition, collimator light may be used as a trigger for the activation of the radiation imaging apparatus 30 when it is set in the power save mode, sleep mode, or the like.

It is necessary to execute reset operation in the radiation imaging apparatus 30 (radiation sensor 32) immediately before (for example, several psec to several min before) imaging. For this reason, the radiation control unit 20 causes the collimator light irradiation unit 14 to irradiate collimator light at a timing several psec to several min before the irradiation of radiation. In general, the operator (radiology technician) irradiates the collimator light receiving unit 31 of the radiation imaging apparatus 30 with collimator light for at least about several ten sec to perform positioning by irradiating collimator light before imaging. In another embodiment described above, after this reset operation, the radiation imaging apparatus 30 outputs an irradiation enable signal.

The switch unit 40 will be described next. The switch unit 40 includes a switch control unit 41 and a switch 42. The switch 42 switches and selects the communication paths between the radiation generator 10 and the plurality of radiation imaging apparatuses 30 to make one-to-one connection between the radiation generator 10 and the radiation imaging apparatus 30. The switch control unit 41 controls the switch 42 based on an instruction from the sensor control unit 33. More specifically, the switch control unit 41 switches the switch 42 in accordance with a control signal from the radiation imaging apparatus 30 (sensor control unit 33) which has received collimator light. This establishes a one-to-one communication path between the radiation control unit 20 which has irradiated collimator light and the radiation imaging apparatus 30 (sensor control unit 33) which has received the collimator light. As described above, some system does not include the switch unit 40, and has a plurality of radiation imaging apparatuses 30 connected to the radiation control unit 20. In this case, it is possible to perform control concerning a transmission destination (radiation imaging apparatus 30) for a control signal from the radiation control unit 20.

The above is a description of an example of the functional arrangement of the radiation imaging system 70. Note that the radiation imaging system 70 incorporates one or a plurality of computers. The computer includes a main control unit such as a CPU and storage units such as a ROM (Read Only Memory) and a RAM (Random Access Memory). In addition, the computer may include a communication unit such as a network card and input/output devices such as a keyboard, a display, and a touch panel. Note that the respective components are connected to each other via a bus and the like. The main control unit executes programs stored in the storage unit to control the components.

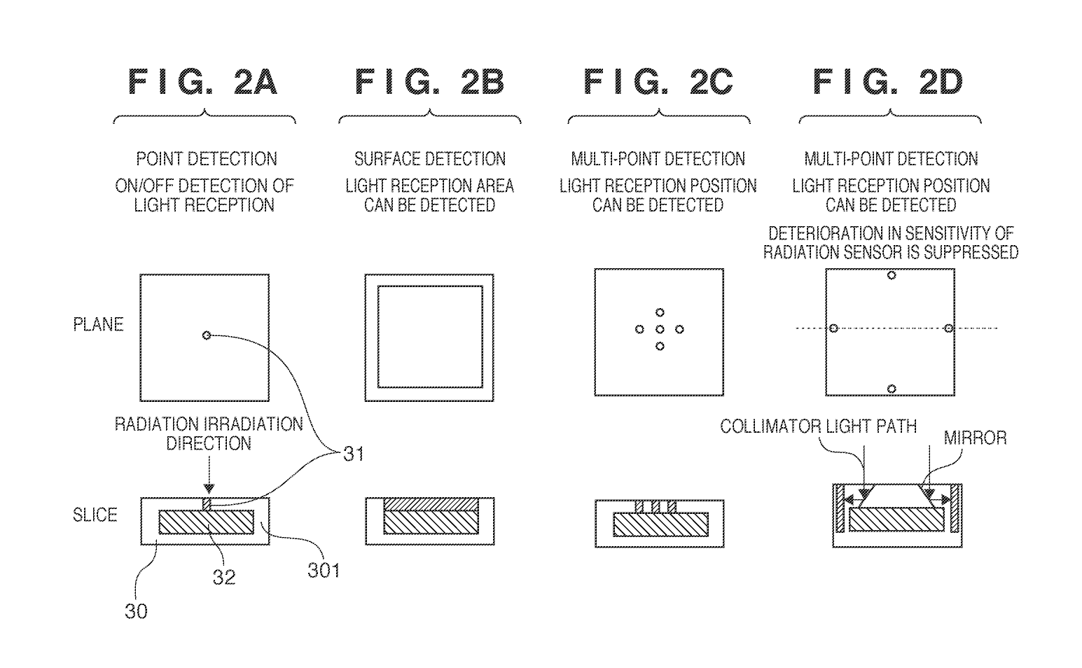

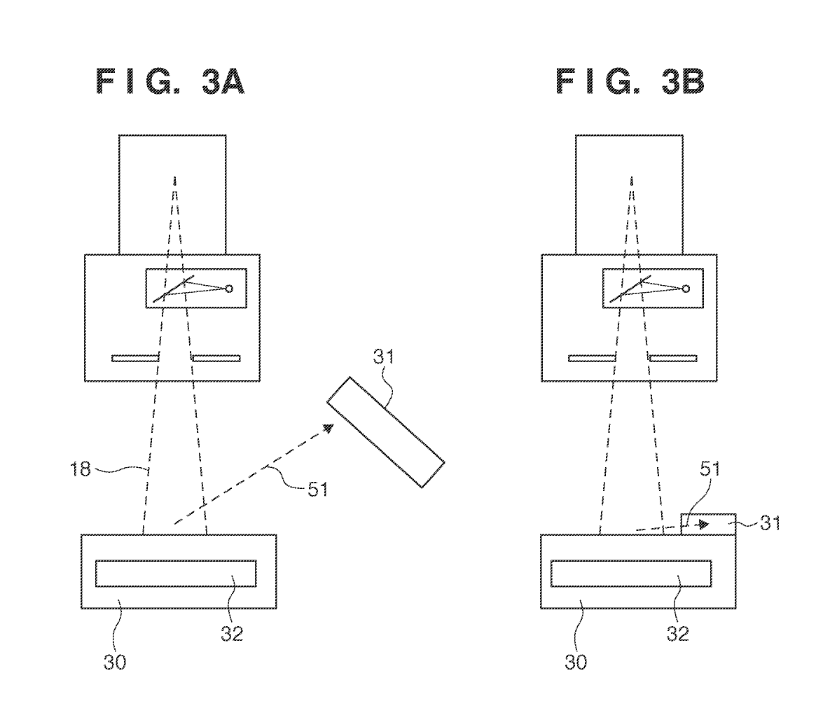

An example of the arrangement relationship between the radiation imaging apparatus 30 and the collimator light receiving unit 31 shown in FIG. 1 will be described with reference to FIGS. 2A to 2D and 3A and 3B.

An example of the arrangement obtained by providing the collimator light receiving unit 31 in the radiation imaging apparatus 30 will be described first with reference to FIGS. 2A to 2D. Four examples of these arrangement relationships will be described with reference to FIGS. 2A to 2D.

In the arrangement in FIG. 2A, the collimator light receiving unit 31 is placed on a portion on the upper side (the radiation irradiation side) of the radiation sensor 32. More specifically, the collimator light receiving unit 31 is provided in a portion of an outer packaging 301 of the radiation imaging apparatus 30. In the arrangement shown in FIG. 2A, since the collimator light receiving unit 31 is provided in the outer packaging 301 of the radiation imaging apparatus 30, the collimator light receiving unit 31 can receive collimator light with high sensitivity.

In the arrangement in FIG. 2B, the collimator light receiving unit 31 is provided at a position similar to that in the above arrangement shown in FIG. 2A. This arrangement differs from that shown in FIG. 2A in the area of the place where the collimator light receiving unit 31 is placed. That is, the arrangement in FIG. 2B includes a light sensor (collimator light receiving unit 31) having a larger area than that in the arrangement in FIG. 2A. Making the collimator light receiving unit 31 have the same (or almost the same) area as that of the radiation sensor 32 can more clearly grasp the shift of the irradiation position of radiation.

In the arrangement in FIG. 2C, the collimator light receiving unit 31 is provided at a position similar to that in the above arrangement in FIG. 2A. This arrangement differs from that shown in FIG. 2A in that the collimator light receiving units 31 are separately arranged. Placing the collimator light receiving unit 31 on the upper side of the radiation sensor 32 may attenuate radiation intensity. This may degrade the sensitivity of a captured image. As shown in FIG. 2C, therefore, the collimator light receiving units 31 are separately arranged. This can locally suppress the attenuation of radiation intensity. In the case in FIG. 2C, since the collimator light receiving units 31 are two-dimensionally arranged at multiple points, it is easy to grasp the shift of the irradiation position of radiation. In addition, the arrangement in FIG. 2C can localize the regions where radiation intensity is attenuated unlike the arrangement in FIG. 2B, and hence can suppress a deterioration in the image quality of an overall frame.

In the arrangement in FIG. 2D, the collimator light receiving units 31 are not arranged on the upper side of the radiation sensor 32 (on the radiation irradiation side), and are arranged side by side with the radiation sensor 32 along a direction perpendicular to the irradiation direction of radiation. The arrangement in FIG. 2D is useful for a case in which the attenuation of radiation due to the positions of the collimator light receiving units 31 is large. In the arrangement in FIG. 2D, only a waveguide for collimator light is provided on the upper side of the radiation sensor 32, and the collimator light receiving units 31 are not provided on it. Note that a material which easily transmits radiation (for example, a half mirror which transmits radiation and reflects visible light) may be used for the collimator light waveguide. Like the arrangement in FIG. 2C, the arrangement in FIG. 2D allows to grasp the shift of the irradiation position of radiation and can suppress a deterioration in the sensitivity of captured images.

An example of the arrangement obtained by providing the collimator light receiving unit 31 outside the radiation imaging apparatus 30 will be described next. Two examples of the arrangement relationship between these components will be described with reference to FIGS. 3A and 3B.

The arrangement in FIG. 3A causes collimator light to be reflected by the surface of the radiation imaging apparatus 30, and makes the collimator light receiving unit 31 receive the reflected light. The position of the collimator light receiving unit 31 is properly adjusted to a position where it can receive reflected light. Reference numeral 51 denotes part of the optical path of reflected light. To make the surface of the radiation imaging apparatus 30 reflect collimator light, for example, an AL film is attached, as a reflecting member, to the sensor surface. Note that it is possible to irregularly reflect collimator light by properly adjusting the irregular surface structure of the reflecting member.

The arrangement in FIG. 3B has the collimator light receiving unit 31 provided outside the radiation imaging apparatus 30 like the arrangement in FIG. 3A described above. The difference from the arrangement in FIG. 3A is that the collimator light receiving unit 31 is placed on the surface of the body of the radiation imaging apparatus 30.

It is difficult to make the surface of the body of the radiation imaging apparatus 30 reflect all light in a predetermined direction, and reflection components include irregular reflection components. The arrangement in FIG. 3B is configured to receive such irregular reflection components. Such a scheme can also sufficiently receive collimator light.

An example of the arrangement relationship between the radiation imaging apparatus 30 and the collimator light receiving unit 31 has been described above with reference to FIGS. 2A to 2D and FIGS. 3A and 3B. This embodiment can use any of the above arrangements. In addition, it is possible to use any arrangement other than the arrangements exemplified above as long as the radiation imaging apparatus 30 (radiation sensor 32) and the collimator light receiving unit 31 can receive radiation and collimator light.

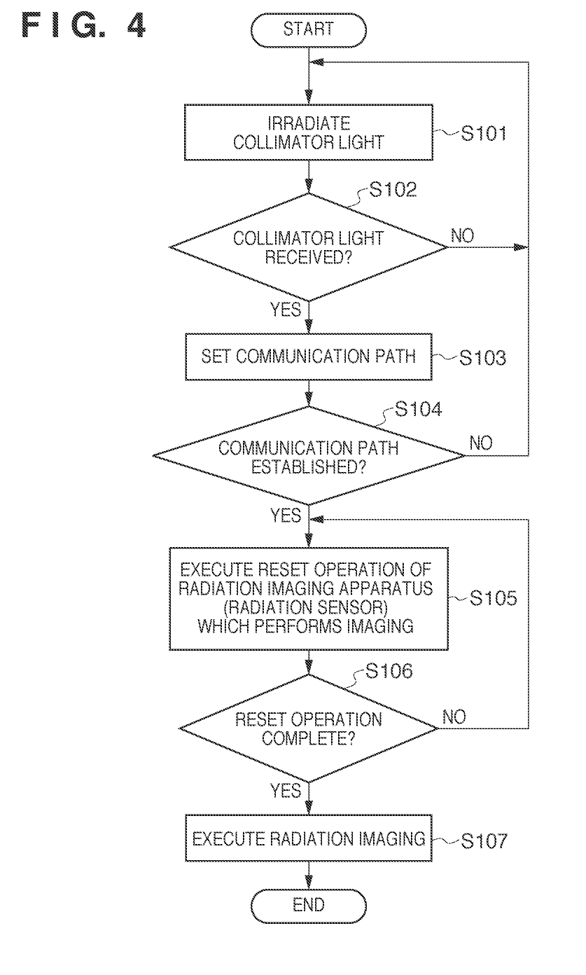

An example of the operation of the radiation imaging system 70 shown in FIG. 1 will be described next with reference to FIG. 4. An example of operation to be performed when radiation imaging is performed will be described below.

When radiation imaging starts, first of all, the radiation imaging system 70 causes the radiation control unit 20 to transmit a control signal to the collimator light irradiation unit 14. This makes the collimator light irradiation unit 14 to start irradiating collimator light (S101). The collimator light irradiation unit 14 keeps irradiating collimator light until the system performs determination processing in step S104. Note that it is possible to keep irradiating collimator light until the end of radiation imaging processing; the irradiation period is not specifically limited.

When the radiation imaging apparatus 30 leaves an imaging enable area (collimator light irradiation area), the radiation imaging apparatus 30 receives collimator light via the collimator light receiving unit 31. This makes the sensor control unit 33 of the radiation imaging apparatus 30 detect the reception of the collimator light. As described above, the radiation imaging apparatus 30 which has received the collimator light becomes the radiation imaging apparatus 30 to be used for imaging.

If none of the radiation imaging apparatuses 30 has confirmed the reception of collimator light (NO in step S102), the radiation imaging system 70 returns to the processing in step S101 again. If any one of the radiation imaging apparatuses 30 has confirmed the reception of collimator light (YES in step S102), the sensor control unit 33 of the radiation imaging apparatus 30 transmits a control signal to the switch control unit 41. This switches the switch 42 to set a communication path to make one-to-one connection between the radiation control unit 20 and the sensor control unit 33 which performs radiation imaging. That is, the radiation imaging apparatus 30 which has received collimator light can communicate with the radiation generator 10 which has irradiated collimator light (S103).

In this case, the radiation imaging apparatus 30 causes the sensor control unit 33 to check a communication path between itself and the radiation control unit 20. More specifically, the sensor control unit 33 transmits a control signal to the radiation control unit 20, and receives a response to the signal from the radiation control unit 20. This confirms the establishment of a communication path. If the establishment of a communication path cannot be confirmed (NO in step S104), the radiation imaging system 70 returns to the processing in step S101 again.

If the establishment of a communication path can be confirmed (YES in step S104), the sensor control unit 33 and the radiation control unit 20 start imaging in synchronism with each other. When imaging processing starts, first of all, the radiation imaging system 70 causes the radiation control unit 20 to transmit a control signal (reset instruction) to instruct the sensor control unit 33 to perform reset operation. This causes the radiation sensor 32 of the radiation imaging apparatus 30 which performs radiation imaging to execute reset operation to remove accumulated charge (S105).

After issuing a reset instruction, the radiation imaging system 70 determines whether the radiation control unit 20 has completed reset operation. More specifically, when the reset operation of the radiation imaging apparatus 30 (radiation sensor 32) is complete, the sensor control unit 33 transmits a control signal indicating the end of reset operation to the radiation control unit 20. This control signal is sometimes called an irradiation enable signal. The radiation control unit 20 determines the end of reset operation based on the reception of this signal. It is possible to determine the end of reset operation when a predetermined period of time has elapsed or to determine the end of reset operation when a measured amount of charge removed is smaller than a predetermined amount.

Upon determining the end of reset operation (YES in step S106), the radiation imaging system 70 causes the radiation control unit 20 to transmit a control signal indicating the start of imaging to the radiation tube 11 and the sensor control unit 33. This causes the radiation tube 11 to start irradiating radiation and the radiation sensor 32 to receive (detect) radiation transmitted through the object (S107). That is, the system performs radiation imaging. Note that the system captures an image of the object placed between the radiation generator 10 and the radiation imaging apparatus 30.

Subsequently, the radiation imaging system 70 causes the radiation control unit 20 to transmit a control signal indicating the end of imaging to the radiation tube 11 and the sensor control unit 33. Upon receiving this signal, the radiation tube 11 finishes the irradiation of radiation, and the radiation sensor 32 finishes the reception (detection) of radiation. The radiation imaging system 70 then causes the sensor control unit 33 to store, in a memory (not shown), a radiographic image based on the accumulated charge received by the radiation sensor 32. With this operation, the radiation imaging processing is complete.

As described above, according to the first embodiment, collimator light receiving units are provided in correspondence with a plurality of radiation sensors. When any one of the collimator light receiving units receives collimator light immediately before the irradiation of radiation, the radiation sensor made to correspond to the light receiving unit executes reset operation. With this operation, the radiation imaging apparatus 30 which is to perform radiation imaging always executes reset operation before the irradiation of radiation.

This makes it possible to easily perform radiation imaging even when a plurality of radiation imaging apparatuses 30 are provided. In addition, for example, the operator (radiology technician or the like) can start radiation imaging without performing any complicated operation by only bringing the radiation sensor into an imaging enable area. In addition, this can suppress low-sensitivity radiation imaging due to, for example, the non-removal of invalid accumulated charge.

Although the above description has exemplified the case in which the intensity of collimator light is constant (almost constant), the present invention is not limited to this. For example, it is possible to modulate collimator light to add an arbitrary signal to the light. If, for example, the system is configured to use collimator light with its intrinsic information modulated by PHM modulation, PWM modulation, or a combination of them, it is possible to perform stable control even when collimator light is light in the same wavelength region as that of environmental light.

In such an arrangement, the sensor control unit 33 has a function of determining from an output signal from the collimator light receiving unit 31 whether collimator light is modulated light. The sensor control unit 33 may also be configured to have a function of demodulating light and extract information superimposed on the light. In this case, it is possible to determine the reception of collimator light with higher accuracy.

As described above, the sensor control unit 33 communicates with the radiation control unit 20 in accordance with light having a predetermined characteristic which is received by the collimator light receiving unit 31 and irradiated on the irradiated region (radiation irradiation area) of the radiation imaging apparatus 30. More specifically, the collimator light receiving unit 31 receives light having intensity higher than that generally measured in an imaging room or light modulated by PHM modulation, PWM modulation, or the like. The sensor control unit 33 then determines in accordance with the light received by the collimator light receiving unit 31 that the radiation imaging apparatus 30 provided with the sensor control unit 33 is positioned in the irradiated region of the radiation imaging apparatus 30.

### Second Embodiment

The second embodiment will be described next. The second embodiment will exemplify a case in which the system includes a plurality of radiation generators 10 and a plurality of radiation imaging apparatuses 30. In order to avoid a redundant description, the difference from the first embodiment will be mainly described below.

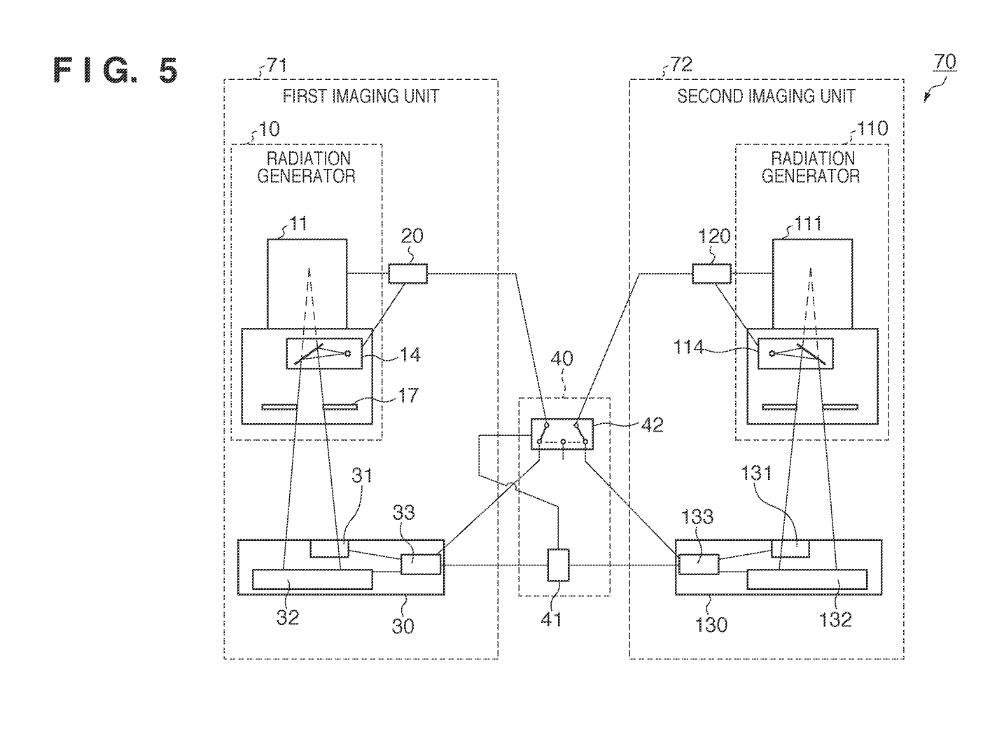

FIG. 5 is a view showing an example of the arrangement of a radiation imaging system 70 according to the second embodiment. Note that the arrangement of the radiation imaging system according to the second embodiment is basically the same as that shown in FIG. 1 described in the first embodiment. The difference from the first embodiment is that the system is provided with a plurality of radiation generators 10 and 110. Note that since the radiation generator 110 has the same function as that of the radiation generator 10, a description of the radiation generator 110 will be omitted.

The functional arrangement of the radiation imaging system 70 according to the second embodiment can be roughly divided into a first imaging unit (a combination of the radiation generator 10 and the radiation imaging apparatus 30) 71 and a second imaging unit (a combination of the radiation generator 110 and a radiation imaging apparatus 130) 72, and a switch unit 40. When the imaging units 71 and 72 simultaneously perform different imaging operations, the communication path between them needs to be separated. That is, each imaging unit needs to independently execute reset operation immediately before imaging.

FIG. 5 shows a state in which the communication paths of a plurality of (two in this case) imaging units 71 and 72 are separated. More specifically, the communication path of the first imaging unit 71 includes a radiation control unit 20, a switch 42, and a sensor control unit 33. The communication path of the second imaging unit 72 includes a radiation control unit 120, the switch 42, and a sensor control unit 133. The first imaging units 71 and 72 have independent communication paths via the switch 42.

In order to make the communication paths independent, the radiation sensors 30 and 130 must be able to determine that the radiation generator 10 and the radiation generator 110 are different devices. In the second embodiment, therefore, the radiation generators 10 and 110 are configured to irradiate collimator light as different signals. For example, the radiation generator 10 (a collimator light irradiation unit 14) irradiates collimator light obtained by modulating the character “1”. The radiation generator 110 (a collimator light irradiation unit 114) irradiates collimator light obtained by modulating the character “2”. That is, identification information for identifying the radiation generator 10 is superimposed on collimator light. Note that these radiation generators irradiate collimator light obtained by modulating these pieces of intrinsic information under the control of the radiation control units 20 and 120.

In an initial state, both the communication paths of the first and second imaging units 71 and 72 are shut off. That is, the sensor control units 33 and 133 are not connected to the radiation control units 20 and 120. In this case, when the radiation imaging apparatus 30 is placed in the imaging enable area of the radiation generator 10, the collimator light receiving unit 31 of the radiation imaging apparatus 30 receives collimator light obtained by modulating the character “1”. The sensor control unit 33 demodulates this signal and receives the character “1”. The sensor control unit 33 then determines, based on the character “1”, that the radiation generator 10 has irradiated the collimator light. The sensor control unit 33 sends a control signal based on the determination result toward a switch control unit 41. With this operation, the switch control unit 41 switches the switch 42. That is, upon receiving the character “1”, the switch control unit 41 switches the switch 42 to establish a communication path between the radiation control unit 20 and the radiation imaging apparatus 30 (sensor control unit 33). Note that in the case of the second imaging unit 72 as well, the second imaging unit 72 and the switch unit 40 execute the same operation as that described above.

Note that after the switch 42 is switched, this embodiment performs check processing for the establishment of a communication path, reset operation, imaging, and the like in the same procedures as those in the first embodiment, and then terminates the processing.

As described above, the second embodiment changes the signal contents of collimator light for each radiation generator. This makes it possible to obtain the same effects as those of the first embodiment even when the system includes a plurality of radiation generators and a plurality of radiation imaging apparatuses (radiation sensors).

Note that the above description does not refer to any modulation schemes for collimator light, the modulation scheme to be used is not specifically limited. For example, it is possible to modulate collimator light by using, for example, PHM modulation, PWM modulation or a combination of them.

### Third Embodiment

The third embodiment will be described next. The third embodiment will exemplify a case in which the system uses collimator light only for collimating radiation, and includes an arrangement other than that described above to implement imaging using any one of the sensors of a plurality of radiation imaging apparatuses 30. In order to avoid a redundant description, the difference from the first embodiment will be mainly described below.

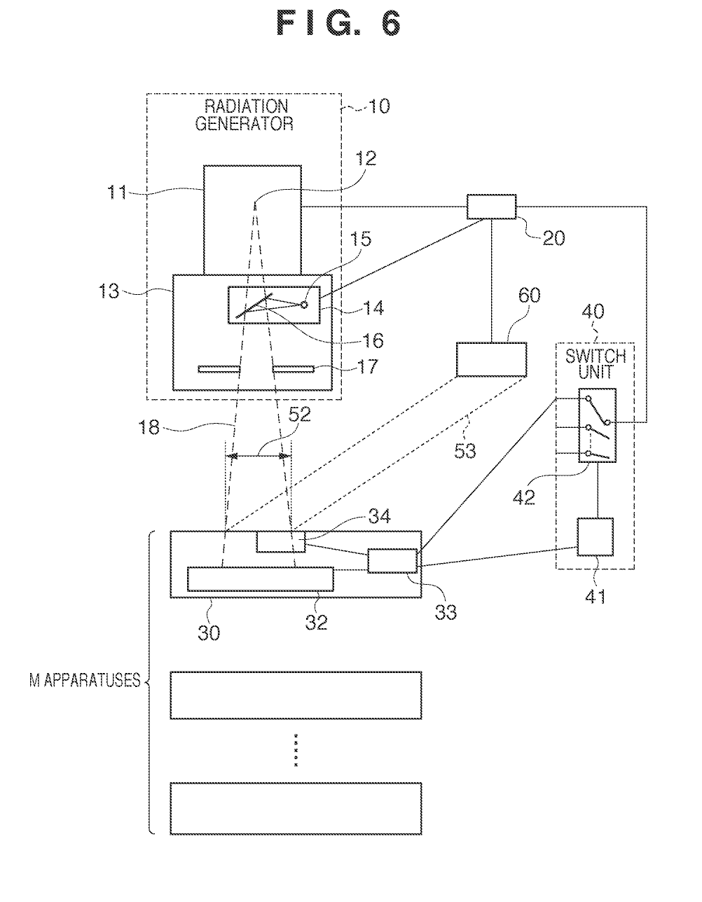

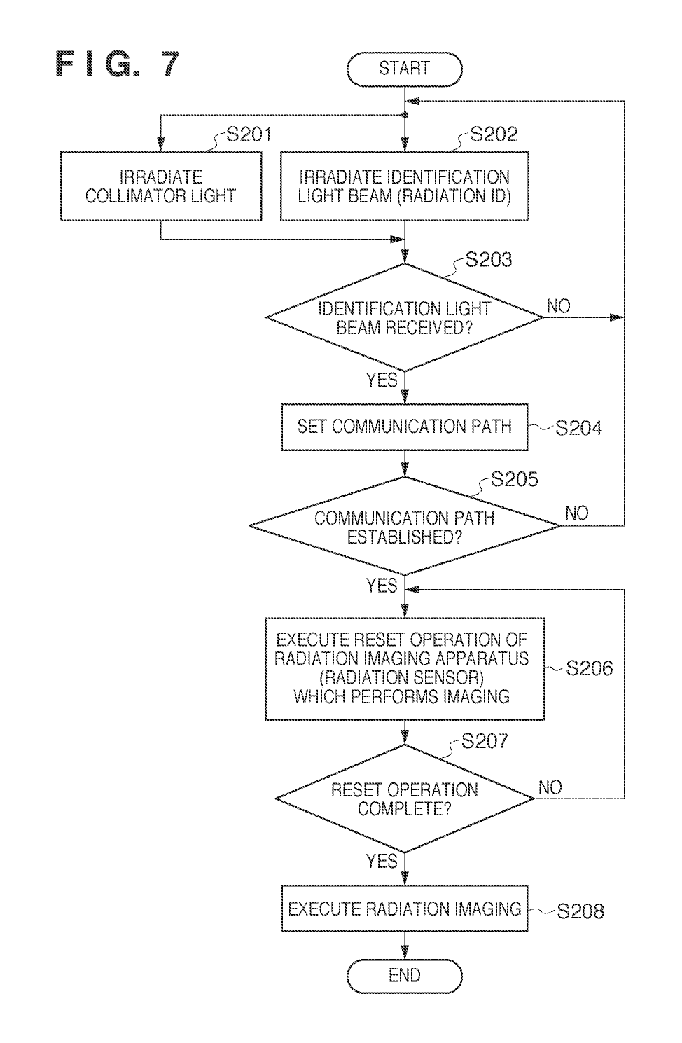

FIG. 6 is a view showing an example of the arrangement of a radiation imaging system 70 according to the third embodiment. Note that the arrangement of the radiation imaging system according to the third embodiment is basically the same as that shown in FIG. 1 described in the first embodiment. The difference from the first embodiment is that the system is newly provided with an identification light beam irradiation unit 60, and a radiation imaging apparatus 30 is provided with an irradiation light beam receiving unit 34 in place of a collimator light receiving unit 31.

A light beam (for example, including a radiation ID) irradiated from the identification light beam irradiation unit 60 may have directivity and be identifiable relative to collimator light. This light beam is irradiated toward an imaging enable area. If, for example, collimator light is red monochromatic light (wavelength: 900 nm), it is possible to use blue monochromatic light (wavelength: about 600 nm) as a light beam irradiated from the identification light beam irradiation unit 60. The optical path of the identification light beam irradiation unit 60 is adjusted to irradiate almost the same area as that irradiated with collimator light with blue monochromatic light.

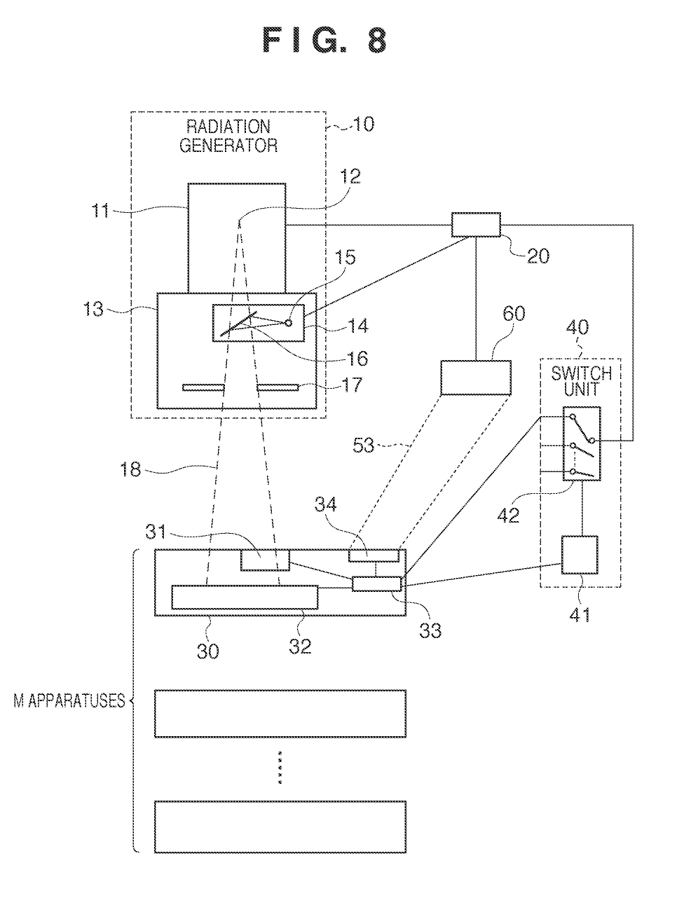

An example of the operation of the radiation imaging system 70 according to third embodiment will be described below with reference to FIG. 7. An example of the operation to be performed when radiation imaging is performed will be described below.

When radiation imaging starts, first of all, the radiation imaging system 70 causes a radiation control unit 20 to transmit a control signal to a collimator light irradiation unit 14 and the identification light beam irradiation unit 60. With this operation, the collimator light irradiation unit 14 starts irradiating collimator light (S201). At the same time, the identification light beam irradiation unit 60 starts irradiating blue monochromatic light (S202). In the third embodiment, as described above, collimator light is used to allow the operator to visually adjust the collimation of radiation. Note that it is not always necessary to irradiate collimator light in step S201, and the system may be configured to not irradiate collimator light.

When the radiation imaging apparatus 30 exists in the imaging enable area, the radiation imaging apparatus 30 receives blue monochromatic light via the irradiation light beam receiving unit 34. With this operation, a sensor control unit 33 of the radiation imaging apparatus 30 detects the reception of blue monochromatic light. The radiation imaging apparatus 30 which has received blue monochromatic light is the radiation imaging apparatus 30 used for imaging.

In this case, if any of the radiation imaging apparatuses 30 has not confirmed the reception of blue monochromatic light (NO in step S203), the radiation imaging system 70 returns to the processing in step S201 again. In contrast, if any one of the radiation imaging apparatuses 30 has confirmed the reception of blue monochromatic light (YES in step S203), the sensor control unit 33 of the radiation imaging apparatus 30 transmits a control signal to a switch control unit 41. With this operation, a switch 42 is switched to set a communication path between the radiation control unit 20 and the sensor control unit 33 which is to perform radiation imaging. That is, the radiation imaging apparatus 30 which has received blue monochromatic light can communicate with a radiation generator 10 (S204).

After this operation, in the processing in steps S205 to S208, this embodiment performs check processing for the establishment of a communication path, reset operation, imaging, and the like in the same procedures as those in the first embodiment, and then terminates the processing.

As described above, the third embodiment can obtain the same effects as those of the first embodiment without changing the conventional radiation generator. Note that the placement of the irradiation light beam receiving unit 34 can be changed as needed as in the case of the placement of the collimator light receiving unit 31 described with reference to FIGS. 2A to 2D and 3A and 3B. For example, the irradiation light beam receiving unit 34 may be a multi-point sensor or may be provided inside or outside the radiation imaging apparatus 30.

Although the above description has exemplified the case in which the wavelength of identification light is changed, the present invention is not limited to this. For example, it is possible to modulate identification light to add an arbitrary signal to the light. If, for example, the system is configured to use identification light with its unique information modulated by PHM modulation, PWM modulation, or a combination of them, it is possible to perform stable control even when identification light is light in the same wavelength region as that of environmental light.

In such an arrangement, the sensor control unit 33 has a function of determining from an output signal from the irradiation light beam receiving unit 34 whether identification light is modulated light. The sensor control unit 33 may also be configured to have a function of demodulating light and extract information superimposed on the light. In this case, it is possible to determine the reception of identification light with higher accuracy.

As described above, the sensor control unit 33 communicates with the radiation control unit 20 in accordance with identification light which is received by the irradiation light beam receiving unit 34 and irradiated on the irradiated region (radiation irradiation area) of the radiation imaging apparatus 30. More specifically, the irradiation light beam receiving unit 34 receives light having a wavelength different from that generally measured in an imaging room or light modulated by PHM modulation, PWM modulation, or the like. The sensor control unit 33 then determines in accordance with the light received by the irradiation light beam receiving unit 34 that the radiation imaging apparatus 30 provided with the sensor control unit 33 is positioned in the irradiated region of the radiation imaging apparatus 30.

### Fourth Embodiment

The fourth embodiment will be described next. The fourth embodiment will exemplify a case in which the system performs radiation imaging processing by using both collimator light and the irradiation/reception of a light beam by the identification light beam irradiation unit 60 and the 34 described in the third embodiment.

FIG. 8 is a view showing an example of the arrangement of a radiation imaging system 70 according to the fourth embodiment. Note that the arrangement of the radiation imaging system according to the fourth embodiment is basically the same as that shown in FIG. 6 described in the third embodiment. The difference from the third embodiment is that a radiation imaging apparatus 30 is provided with a collimator light receiving unit 31.

A light beam (for example, including a radiation ID) irradiated from an identification light beam irradiation unit 60 according to the fourth embodiment may have directivity and be identifiable relative to collimator light. Note however that this light beam need not strictly be directive to an imaging enable area as compared with the third embodiment, and may have directivity enough to allow to discriminate adjacent radiation sensors 32 from each other. Since a plurality of radiation imaging apparatuses 30 are spaced apart from each other by 1 m or more in a normal operating environment, for example, infrared light (wavelength: 1 μm to 1 mm) may be used as a light beam irradiated from the identification light beam irradiation unit 60. Note that the fourth embodiment does not use this light beam alone for specifying the radiation imaging apparatus 30 to be used for imaging, but specifies the radiation imaging apparatus 30 based on the light beam and collimator light. If, for example, a light beam irradiated from the identification light beam irradiation unit 60 is, for example, infrared light (wavelength: 1 μm to 1 mm), white light (wavelength: 400 nm to 800 nm) may be used as collimator light.

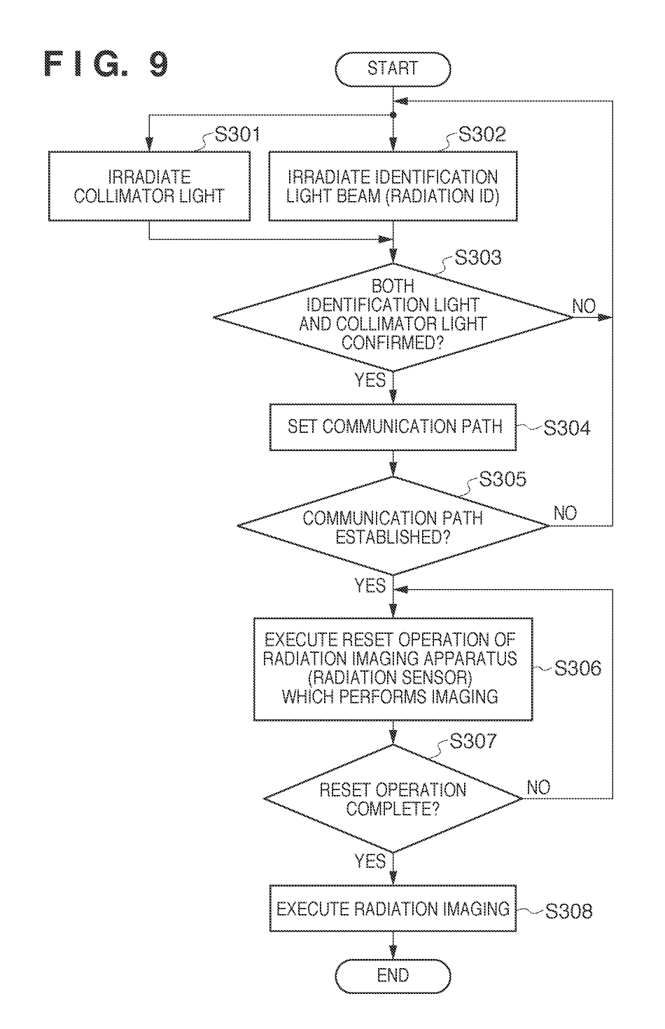

An example of the operation of the radiation imaging system 70 according to the fourth embodiment will be described below with reference to FIG. 9. An example of the operation to be performed when radiation imaging is performed will be described below.

When radiation imaging starts, first of all, the radiation imaging system 70 causes a radiation control unit 20 to transmit a control signal to a collimator light irradiation unit 14 and an identification light beam irradiation unit 60. This makes the collimator light irradiation unit 14 start irradiating collimator light (S301). At the same time, the identification light beam irradiation unit starts irradiating infrared light (S302).

When the radiation imaging apparatus 30 exists in the imaging enable area, the radiation imaging apparatus 30 receives collimator light via the collimator light receiving unit 31, and simultaneously receives infrared light via an irradiation light beam receiving unit 34. With this operation, a sensor control unit 33 of the radiation imaging apparatus 30 detects (simultaneously) the reception of both collimator light and infrared light. The radiation imaging apparatus 30 which has received both (simultaneously) the collimator light and the infrared light is the radiation imaging apparatus 30 to be used for imaging.

In this case, if any of the radiation imaging apparatuses 30 has not confirmed the reception of both (simultaneously) collimator light and infrared light (NO in step S303), the radiation imaging system 70 returns to the processing in step S301 again. In contrast, if any one of the radiation imaging apparatuses 30 has confirmed the reception of both (simultaneously) collimator light and infrared light (YES in step S303), the sensor control unit 33 of the radiation imaging apparatus 30 sends a control signal to a switch control unit 41. With this operation, a switch 42 is switched to set a communication path between the radiation control unit 20 and the sensor control unit 33 which is to perform radiation imaging. That is, the radiation imaging apparatus 30 which has received both (simultaneously) collimator light and infrared light can communicate with a radiation generator 10 (S304).

After this operation, in the processing in steps S305 to S308, this embodiment performs check processing for the establishment of a communication path, reset operation, imaging, and the like in the same procedures as those in the first embodiment, and then terminates the processing.

As described above, the fourth embodiment can obtain the same effects as those of the first embodiment without changing the conventional radiation generator.

Note that the first to fourth embodiment described above have exemplified the case in which collimator light is visible light. However, the present invention is not limited to this. For example, collimator light may be light including visible light. Collimator light is preferably visible light to allow the operator to visually recognize it for the collimation of radiation. However, the radiation imaging system 70 checks the position of the radiation imaging apparatus 30, collimator light is not limited to visible light. That is, collimator light can be any light beam which is sensible, and it is possible to use light in the ultraviolet light or infrared light region other than visible light.

A communication path in the radiation imaging system 70 may be implemented by a wire cable or wirelessly. For example, a communication path between the radiation generator 10 and the radiation imaging apparatus 30 may be implemented wirelessly or by Ethernet®, TCP/IP, or telnet. In this case as well, the above processing can be performed.

### Fifth Embodiment

The fifth embodiment will be described next. The fifth embodiment will exemplify a case in which the arrangement shown in FIG. 1 described in the first embodiment is applied to an actual operating environment (a hospital in this case).

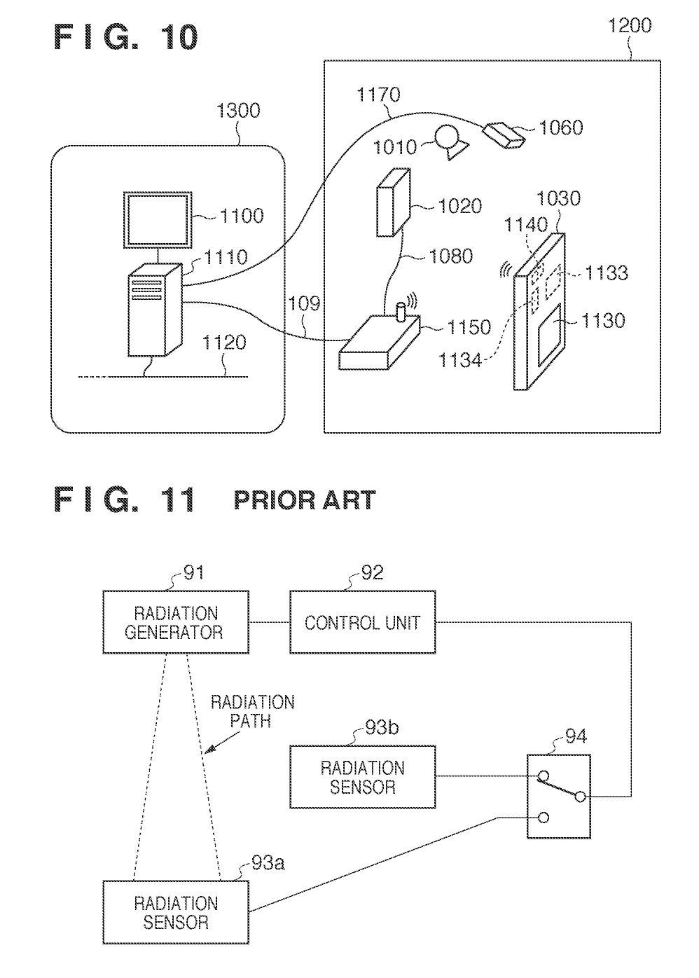

An example of the arrangement of a digital radiation imaging system (for example, a radiation imaging system 70) will be described with reference to FIG. 10.

In a radiation room 1200, this system performs radiation imaging by irradiating radiation. A control room 1300 is installed near the radiation room 1200. The operator issues various instructions from the control room 1300. This causes the system to perform radiation imaging.

The radiation room 1200 is provided with a radiation generating apparatus 1010, a radiation control apparatus 1020, a radiation imaging apparatus 1030, an identification light beam irradiation unit 1060, and an access point 1150. The control room 1300 is provided with a display apparatus 1100 and an image processing apparatus 1110.

In general, the operator performs radiation imaging while fixing the radiation imaging apparatus 1030 on a holder or base. In some cases, however, in order to perform radiation imaging with a higher degree of freedom, the operator performs imaging while holding the radiation imaging apparatus 1030 in a free position instead of mechanically fixing it. To meet such needs, there has recently been available a digital radiation imaging apparatus of a type that has improved the degree of freedom of installation of the radiation imaging apparatus 1030 by wirelessly connecting the radiation imaging apparatus 1030 to the radiation control apparatus 1020.

The radiation generating apparatus 1010 corresponds to the radiation generator 10 described above. This apparatus generates radiation and irradiates an object with the radiation.

The radiation imaging apparatus 1030 corresponds to the radiation imaging apparatus 30 described above. This apparatus generates digital radiographic image data information in response to radiation. The radiation imaging apparatus 1030 includes a battery 1130, a wireless communication unit 1140, a sensor control unit 1133, and an identification light beam receiving unit 1134. The battery 1130 supplies power to the respective units of the radiation imaging apparatus 1030. The wireless communication unit 1140 wirelessly communicates with the access point 1150. Note that IEEE802.11 specifications or the like may be used for wireless communication with the access point 1150. The sensor control unit 1133 corresponds to the sensor control unit 33 described above. The identification light beam receiving unit 1134 corresponds to the irradiation light beam receiving unit 34 described above.

The radiation control apparatus 1020 corresponds to the radiation control unit 20 described above. This apparatus sends the digital radiographic image data information received from the radiation imaging apparatus 1030 to the image processing apparatus 1110, and controls the generation of radiation by the radiation generating apparatus 1010. Note that this system may include a plurality of radiation generating apparatuses 1010 and a plurality of radiation control apparatuses 1020.

The identification light beam irradiation unit 1060 irradiates the radiation irradiated region of the radiation generating apparatus 1010 with light on which wireless parameters including information for wireless communication with the access point 1150 are superimposed. The identification light beam irradiation unit 1060 corresponds to the identification light beam irradiation unit 60 described above. Note that the identification light beam irradiation unit 1060 may have an arrangement corresponding to the collimator light irradiation unit 14 described above. That is, it is possible to use an arrangement using collimator light itself as an identification arrangement.

The image processing apparatus 1110 is implemented by a PC (Personal Computer) or the like, and performs image processing. A backbone network 1120 is, for example, a hospital LAN (Local Area Network), which connects the image processing apparatus 1110 to other apparatuses in the hospital.

The access point 1150 is placed to face the wireless communication unit 1140 provided in the radiation imaging apparatus 1030, and communicates with the wireless communication unit 1140. The access point 1150 also communicates with the radiation control apparatus 1020 and the image processing apparatus 1110.

The sensor control unit 1133 makes setting for the wireless communication unit 1140 in accordance with wireless parameters superimposed on the identification light received by the identification light beam receiving unit 1134. With this operation, the radiation imaging apparatus 1030 establishes wireless communication with the radiation control apparatus 1020 via the access point 1150.

In this case, the radiation imaging apparatus 1030 operates on power supplied from the battery 1130, and wirelessly communicates with the access point 1150 by using the wireless communication unit 1140. With this operation, the radiation imaging apparatus 1030 transmits captured radiographic image data information and exchanges control information. A wired connection 1170 is implemented by USB (Universal Serial Bus) or the like, which connects the identification light beam irradiation unit 1060 to the image processing apparatus 1110.

This will establish wireless communication between the radiation control apparatus 1020 and the radiation imaging apparatus 1030 in the irradiated region of the radiation generating apparatus 1010. Since information necessary for wireless communication is sent to only the irradiated region of the radiation imaging apparatus 1030, even if a plurality of radiation imaging apparatuses exist, communication is established with only the radiation imaging apparatus 1030 in the irradiated region of the radiation generating apparatus 1010.

In this manner, the sensor control unit 1133 communicates with the radiation control apparatus 1020 in accordance with the information superimposed on identification light received by the identification light beam receiving unit 1134 (irradiated on the irradiated region of the radiation imaging apparatus 30).

The typical embodiments of the present invention have been described above. However, the present invention is not limited to the embodiments described above and shown in the accompanying drawings, and can be modified and executed as needed within the spirit and scope of the invention.

In addition, the present invention can take embodiments as a system, apparatus, method, program, storage medium, and the like. More specifically, the present invention can be applied to a system including a plurality of devices, or to an apparatus including a single device.

### Other Embodiments

Aspects of the present invention can also be realized by a computer of a system or apparatus (or devices such as a CPU or MPU) that reads out and executes a program recorded on a memory device to perform the functions of the above-described embodiment(s), and by a method, the steps of which are performed by a computer of a system or apparatus by, for example, reading out and executing a program recorded on a memory device to perform the functions of the above-described embodiment(s). For this purpose, the program is provided to the computer for example via a network or from a recording medium of various types serving as the memory device (for example, computer-readable storage medium).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-032903 filed on Feb. 17, 2010 and No. 2010-264295 filed on Nov. 26, 2010, which are hereby incorporated by reference herein in their entirety.

What is claimed is:

1. A radiation imaging apparatus comprising:
a radiation imaging unit configured to capture an image based on radiation irradiated by a radiation generator;
a light receiving unit configured to receive light irradiated on an irradiated region of the radiation generator; and
a control unit configured to communicate with a control apparatus of the radiation generator in accordance with reception of light by said light receiving unit.

2. The apparatus according to claim 1, wherein said control unit establishes communication with the control apparatus of the radiation generator if light received by said light receiving unit has any one of characteristics including a predetermined intensity, a predetermined wavelength, and a predetermined modulation.

3. The apparatus according to claim 1, wherein identification information for specifying one of a plurality of radiation generators is superimposed on light received by said light receiving unit, and
said control unit establishes communication with the control apparatus of the radiation generator specified by the identification information.

4. The apparatus according to claim 1, wherein said control unit executes reset operation of removing accumulated charge in said radiation imaging unit in accordance with reception of light by said light receiving unit.

5. The apparatus according to claim 1, wherein light which is irradiated on the irradiated region is irradiated via a collimator of the radiation generator.

6. The apparatus according to claim 1, wherein communication by said control unit is wireless communication.

7. A processing method for a radiation imaging apparatus, comprising:
capturing an image based on radiation irradiated by a radiation generator;
receiving light irradiated on an irradiated region of the radiation generator; and
communicating with a control apparatus of the radiation generator in accordance with reception of light.

8. A radiation generating apparatus comprising:
a radiation generating unit configured to emit radiation via a collimator;
a light source configured to emit visible light via the collimator; and
a modulation unit configured to apply a predetermined modulation to light emitted by said light source.

9. A radiation imaging system comprising a radiation generating apparatus and a radiation imaging apparatus,
said radiation generating apparatus comprising
a radiation generating unit configured to irradiate radiation via a collimator, and
an illumination unit configured to irradiate light on an irradiated region of said radiation generating unit, and
said radiation imaging apparatus comprising
a radiation imaging unit configured to capture an image based on radiation irradiated by said radiation generating unit;
a light receiving unit configured to receive light irradiated on an irradiated region of said radiation generating unit; and
a control unit configured to communicate with a control apparatus of said radiation generating unit in accordance with reception of light by said light receiving unit.
